(19) United States
(12) Patent Application Publication
(10) Pub. No.: US 2021/0310307 A1
(43) Pub. Date: Oct. 7, 2021

(54) PROCESS FOR REAL TIME GEOLOGICAL LOCALIZATION WITH REINFORCEMENT LEARNING

(71) Applicant: SHELL OIL COMPANY, Houston, TX (US)

(72) Inventors: Neilkunal PANCHAL, Houston, TX (US); Sami Mohammed Khair SULTAN, Houston, TX (US); Jeremy Paul VILA, Houston, TX (US); Minith Bharat JAIN, Bhiwandi (IN); David THANOON, Houston, TX (US); Misael Jacobo UZCATEGUI DIAZ, Houston, TX (US); Arnab CHATTERJEE, London (GB)

(21) Appl. No.: 17/263,999

(22) PCT Filed: Jul. 30, 2019
(86) PCT No.: PCT/US2019/044042

§ 371 Date: Jan. 28, 2021

Related U.S. Application Data
(60) Provisional application No. 62/712,518, filed on Jul. 31, 2018.

(30) Foreign Application Priority Data
Sep. 14, 2018 (EP) 18194788.8

(51) Int. Cl. E21B 7/04; G01V 99/00; G06F 30/27; G06N 7/00; G06N 20/00

(52) U.S. Cl. CPC E21B 7/04; G01V 99/005; G06F 30/27; E21B 2200/22; G06N 20/00; E21B 2200/20; G06N 7/005

(57) ABSTRACT

A method of geosteering in a wellbore construction process uses an earth model that defines boundaries between formation layers and petrophysical properties of the formation layers in a subterranean formation. Sensor measurements related to the wellbore construction process are inputted to the earth model. An estimate is obtained for a relative geometrical and geological placement of the well path with respect to a geological objective using a trained reinforcement learning agent. An output action based on the sensor measurement for influencing a future profile of the well path with respect to the estimate.

### FIELD OF THE INVENTION

The present invention relates to the field of geosteering and, in particular, to a process for real time geological localization with reinforcement learning for automating parts of a geological steering workflow.

### BACKGROUND OF THE INVENTION

In a well construction process, rock destruction is guided by a drilling assembly. The drilling assembly includes sensors and actuators for biasing the trajectory and determining the heading in addition to properties of the surrounding borehole media. The intentional guiding of a trajectory to remain within the same rock or fluid and/or along a fluid boundary, such as an oil/water contact or an oil/gas contact, is known as geosteering.

The objective in drilling wells is to maximize the drainage of fluid in a hydrocarbon reservoir. Multiple wells placed in a reservoir are either water injector wells or producer wells. The objective is maximizing the contact of the wellbore trajectory with geological formations that: are more permeable, drill faster, contain less viscous fluid, and contain fluid of higher economical value. Furthermore, drilling more tortuous wells, slower, and out of zone add to the costs of the well.

Geosteering is drilling a horizontal wellbore that ideally is located within or near preferred rock layers. As interpretive analysis is performed while or after drilling, geosteering determines and communicates a wellbore's stratigraphic depth location in part by estimating local geometric bedding structure. Modern geosteering normally incorporates more dimensions of information, including insight from downhole data and quantitative correlation methods. Ultimately, geosteering provides explicit approximation of the location of nearby geologic beds in relationship to a wellbore and coordinate system.

Geosteering relies on mapping data acquired in the structural domain along the horizontal wellbore and into the stratigraphic depth domain Relative Stratigraphic Depth (RSD) means that the depth in question is oriented in the stratigraphic depth direction and is relative to a geologic marker. Such a marker is typically chosen from type log data to be the top of the pay zone/target layer. The actual drilling target or “sweet spot” is located at an onset stratigraphic distance from the top of the pay zone/target layer.

In an article by H. Winkler (“Geosteering by Exact Inference on a Bayesian Network” Geophysics 82:5:D279-D291; September-October 2017), machine learning is used to solve a Bayesian network. For a sequence of log and directional survey measurements, and a pilot well log representing a geologic column, a most likely well path and geologic structure is determined.

There remains a need for autonomous geosteering processes with improved accuracy.

### SUMMARY OF THE INVENTION

According to one aspect of the present invention, there is provided a method of geosteering in a wellbore construction process, the method comprising the steps of: providing an earth model defining boundaries between formation layers and petrophysical properties of the formation layers in a subterranean formation comprising data selected from the group consisting of seismic data, data from an offset well and combinations thereof; comparing sensor measurements related to the wellbore construction process to the earth model; obtaining an estimate from the earth model for a relative geometrical and geological placement of the well path with respect to a geological objective using a trained reinforcement learning agent; and determining an output action based on the sensor measurement for influencing a future profile of the well path with respect to the estimate.

### BRIEF DESCRIPTION OF THE DRAWINGS

The method of the present invention will be better understood by referring to the following detailed description of preferred embodiments and the drawings referenced therein, in which:

FIG. 1 is a flow diagram illustrating one embodiment of the method of the present invention;

FIG. 2 illustrates one embodiment of a work flow of the method of the present invention;

FIG. 3 illustrates another embodiment of a work flow of the method of the present invention;

FIG. 4 is a graphical representation of the results of a first test of a simulation environment produced according to the method of the present invention;

FIG. 5 is a graphical representation of the results of a second test of a simulation environment produced according to the method of the present invention;

FIG. 6 is a graphical representation of the results of a third test of a simulation environment produced according to the method of the present invention; and

FIG. 7 is a graphical representation of the results of a fourth test of a simulation environment produced according to the method of the present invention

### DETAILED DESCRIPTION OF THE INVENTION

The present invention provides a method for geosteering in a wellbore construction process. A wellbore construction process can be a wellbore drilling process. The method is advantageously conducted while drilling. The method uses a trained reinforcement learning agent. The method is a computer-implemented method.

In accordance with the present invention, an earth model is provided. The earth model defines boundaries between formation layers and petrophysical properties of the formation layers of a subterranean formation. The earth model is produced from data relating to a subterranean formation, the data selected from the group consisting of seismic data, data from an offset well and combinations thereof. Preferably, the earth model is a 3D model.

The earth model may be a static or dynamic model. Preferably, the earth model is a dynamic model that changes dynamically during the drilling process.

Sensor measurements are inputted to the earth model. The sensor measurements are obtained during the wellbore construction process. Accordingly, real-time sensor measurements are made while drilling. In a real-time drilling process, sensors are chosen based on the geological objectives. if the target reservoir and the surrounding medium can be distinguished by a particular measurement, then this measurement will be chosen. Since there is a limit of the telemetry rate, the sample frequency would also be budgeted. Preferably, the sensor measurements are provided as a streaming sequence. The sensors may be LWD sensors, MWD sensors, image logs, 2D seismic data, 3D seismic data and combinations thereof.

The LWD sensor may be selected from the group consisting of gamma-ray detectors, neutron density sensors, porosity sensors, sonic compressional slowness sensors, resistivity sensors, nuclear magnetic resonance, and combinations thereof.

The MWD sensor is selected from the group consisting of sensors for measuring mechanical properties, inclination, azimuth, roll angles, and combinations thereof.

The earth model simulates the earth and then a sensor measurement from the earth. The simulated sensor measurement is then compared to an actual sensor measurement made while drilling.

A well path is selected to reach a geological objective, such as a geological feature, such as fault, a nearby offset well, a fluid boundary and the like. Examples of fluid boundaries may be oil/water contacts, oil/gas contacts, oil/tar contacts, and the like. An estimate for the relative geometrical and geological placement of a well path to reach the geological objective is obtained using a trained reinforcement learning agent. An output action based on the sensor measurement for influencing a future profile of the well path is determined with respect to the estimate.

The trained reinforcement learning agent is preferably a trained Bayesian reinforcement learning (BRL) agent or a trained Monte Carlo Trajectory Sampling (MCTS) reinforcement learning agent.

Preferably, a component of the trained BRL agent is a Markov Decision Process (MDP). The data used for training may be historical or synthetic data.

The trained MCTS reinforcement learning agent is defined with respect to a distribution over RSD transitions where the distribution is determined from a Monte Carlo Tree Search.

In a preferred embodiment, the output action of the reinforcement learning agent is determined by maximizing the placement of the well path with respect to a geological datum. An objective is maximizing the contact of the wellbore trajectory with geological formations that: are more permeable, drill faster, contain less viscous fluid, and contain fluid of higher economical value. The geological datum can be, for example, without limitation, a rock formation boundary, a geological feature, an offset well, an oil/water contact, an oil/gas contact, an oil/tar contact and combinations thereof.

The steering of the wellbore trajectories is achieved through a number of different actuation mechanisms, including, for example, rotary steerable systems (RSS) or positive displacement motors. The former contains downhole actuation, power generation feedback control and sensors, to guide the bit by either steering an intentional bend in systems known as point-the-bit or by applying a sideforce in a push-the-bit system. PDM motors contain a fluid actuated Moyno motor that converts hydraulic power to rotational mechanical power for rotating a bit. the motor contains a bend such that the axis of rotation of the bit is offset from the centerline of the drilling assembly. Curved boreholes are achieved through circulating fluid through the motor and keeping the drill-string stationary. Curved boreholes are achieved through rotating the drill string whilst circulating such that the bend cycle averages to obtain a straight borehole.

The output action can be curvature, roll angle, set points for inclination, set points for azimuth, Euler angle, rotation matrix quaternions, angle axis, position vector, position Cartesian, polar, and combinations thereof.

In a preferred embodiment, the estimate for a relative geometrical and geological placement of the well path is determined by providing to the trained reinforcement learning agent a state space representation for a given depth for a position and a direction of the well path and the geological datum, having a discretized representation of the output action as a set of plausible geological datum changes; a state transition function for determining a transition between the state space representation at depth t and depth t+1 conditional upon the output action; an observational model for modeling the sensor measurements to the earth model; a reward function; a discount rate applied to the reward function for determining a discounted reward function; and a value function representing a past sum of discounted rewards for the transition of depth running forward in time.

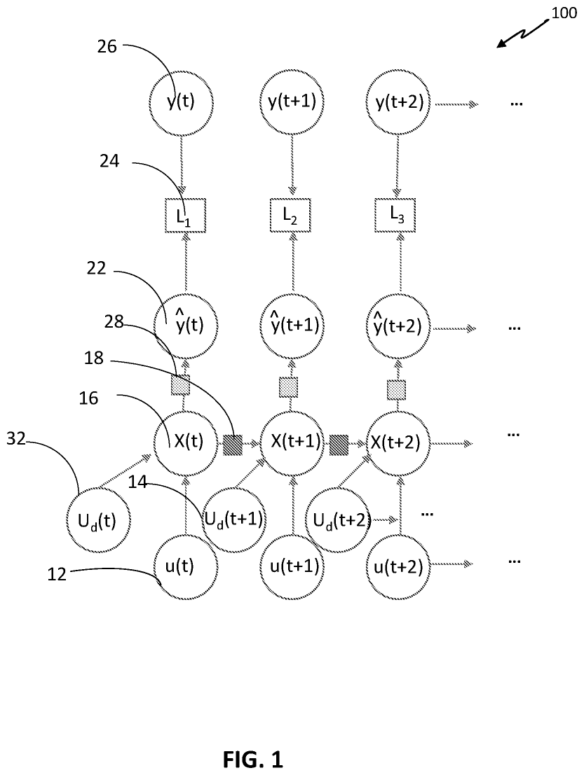

Referring now to FIG. 1, a flow diagram of the method 100 of one embodiment of the present invention is illustrated, where the trained reinforcement learning agent is a BRL agent. As illustrated, u(t) is the control vector 12 for influencing the drilling process. An example of the control vector 12 may be u_{tf} toolface angle, an inclination set point, and the like. Edge 14 representing the mapping from control to state. x(t), denoted by reference numeral 16, is the state vector such as position and heading. A state transition model 18 is represented by P(x(t+1)|x(t)), where x(t+1)=f(x(t), u(t)) is a dynamical system response. The predicted output 22 simulates a sensor measurement. The method 100 includes a loss function or error function 24, sequential data 26, an observation model 28 and a formation interpretation decision variable 32.

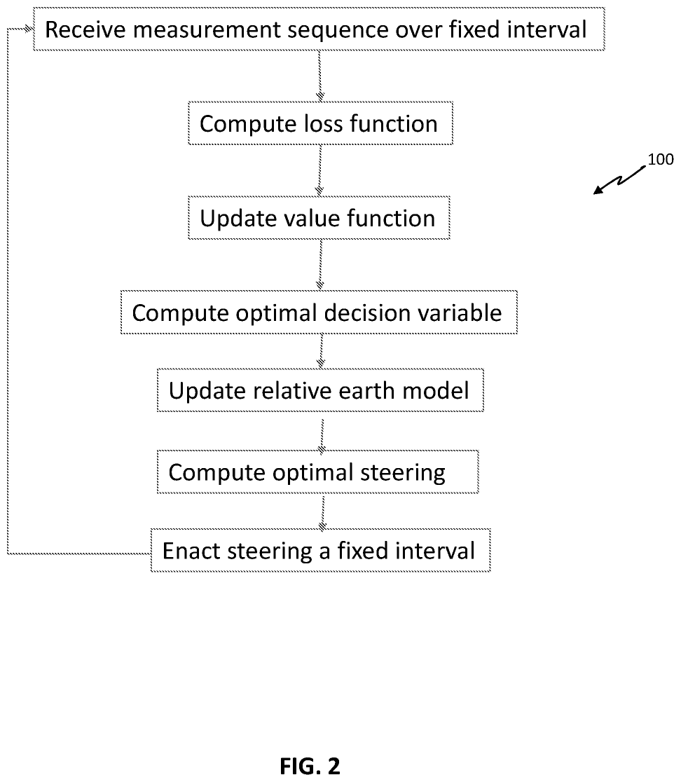

FIG. 2 illustrates one embodiment of a work flow for drilling, where the trained reinforcement learning agent is a BRL agent.

Preferably, an optimal output action for a most probable well path is solved with respect to the value function to minimize or maximize the expected sum of the reward function at a given depth. An optimum value function is determined by iterating on a maximum or minimum of the expected sum of the reward function at depth t with the value of the state space at depth t−1 with respect to state transition function, selecting the highest value state with respect to a constraint, and propagating forward in depth the output actions to determine an optimum formation interpretation.

Preferably, the state space is continuous.

In a preferred embodiment, the state transition function is pretrained on historical wells and or synthetic data. The function may be trained on a neural network and/or a probabilistic graphical model. The probabilistic graphical model may be a Dirichlet-multinomial exponential family conjugate prior representation where the hyper parameters are trained by counting state visits.

Preferably, the discounted sum of rewards is based on discretized depth intervals in an arc length of the well path. The reward function is selected from the group consisting of a sequence similarity measure, a mean squared error reward function, a Huber loss reward function, a non-convex reward function and combination thereof.

Preferably, the observation model is a look-up from a type log or the earth model.

In accordance with the present invention, a propagating borehole accumulates arclength sϵR. It is assumed that the geosteering problem is reduced to a 2D problem because of the horizontal rock layers. In this 2D section the position of the bit is defined as x=(x_{tvd}, x_{xsec})ϵR², where x_{tvd} is the true vertical depth defined to be positive vertically and x_{xsec} is the vertical departure in the 2D cross section.

The formations are assumed to be parallel and unfaulted. The top of a given reference formation of interest is given as x((x_{xsec}). When geosteering with respect to a reference formation, the relative stratigraphic distance defined with respect to this formation is defined to be x_{rsd}=x_{tvd}(x_{xsec})−x_{f} (x_{xsec}). The geosteering problem of this paper refers to a single measurement with respect to an offset reference well. The measurement of the reference well is denoted γₜ(x_{rsd}) representing gamma ray counts with respect to relative stratigraphic depth x_{rsd}. The propagating drilling assembly measures the surrounding medium and returns a measurement γ_{w}(s). The objective of the geosteering optimization problem of this paper is to determine the relative stratigraphic position of the wellbore x_{rsd}(x_{xsec}), from the observations γ_{w}(s) with respect to the reference well γₜ(x_{rsd}).

A Markov decision process (X,U,P,R,γ) is a 5-tuple where S is a set of states, A is a finite set of actions, P(x(t+1)|x(t),u(t)) is the probability that state x(t) at time t and control u(t) will lead to state x(t+1) at time t+1, R(x(t+1), x(t), u(t)) is the reward from transitioning from state x(t) at time t to state x(t+1) at time t+1 due to control action u(t) and γϵ[0,1] is the discount rate.

The goal of an MDP problem is to find a policy n(x(t)) that minimizes a value function V(x(t)) where

$$V ( x ( t ) ) = {\sum }_{t = 0}^{t = ∞} r ( x ( ( t ) , x ( ( t + 1 ) u ( t ) )$$

and to choose an action u(t)ϵπ(x(t)) that maximizes the value function V(x(t))

$$u ( t ) = π ( x ( t ) ) = arg max π {\sum }_{t = 0}^{t = ∞} r ( x ( ( t ) , x ( ( t + 1 ) u ( t ) )$$

In a geosteering problem, a Markov decision process has a state space defined as X={x_{rsd}(t)ϵx_{rsd0}, x_{rsd1}, . . . , x_{rsdn}} where nϵN to be a finitely spaced discrete set of positions representing stratigraphic distances relative to a formation boundary.

x_{rsd}(t=1)=x_{rsd}(t)+β(u_{fdip}(t)−u_{inc}(t))+η

where the noise is normally distributed

η˜N(μ,σ²)

with mean μ and variance σ². The formation dip angle is denoted by u_{dip}(t)ϵ(0,π) and the inclination angle is u_{inc}(t)ϵ(0,π). For the geosteering problems, the inclination angle is known albeit noisy and the goal of a geosteerer is to determine the sequence of dip angles to determine the relative stratigraphic position trajectory in the real-tie process.

x_{rsd}(t+d)=x_{rsd}(t)+u_{dip}(t)+η

where u_{dip}(t)=β(u_{fdip}(t)−u_{inc}(t))∈U.

For learning the Markov decision process, assume a state transition function which represents the system dynamics given by:

P(x(t+d)|x(t),u(t))=η

x(t+d)=x(t)+u_{d}+η

This is a simple linear approximation of the real dynamics Once learned this model can be used to optimize the formation interpretation algorithm in the dynamic programming step.

V(x(t))=maxₐE{r(x(t),u(t))+\gammaV(x(t+1))}

Given a discretization of x(t), u(t) and x(t+d) into a user defined finite interval, where u(t) is the decision variable, then the dynamics P(x(t+d)|x(t),u(t)) can be thought of as a 3D array. The first step to learning this model is to process historical data into a buffer such that for a given t and d each state, control and next state is lined up. Make sure that d is appropriately chosen for if it is too small than the state transitions will not be captured, if too large than the linear approximation to the dynamics no longer become valid.

A nave way of learning this model is to update the count in the table corresponding to the triple for each transition encountered in the data and then to normalize the row across the x(t+d) row. A better way to learn this model using Bayesian methods would be to assign a prior Dirichlet distribution D(αᵢ) for each state and control x(t) and u(t) to represent the distribution over next states x(t+d).

This provides a prior distribution of the entire system dynamics by productizing over all controls and states such that

$$P ( x ( t + d ) \vert x ( t ) , u ( t ) ) = {\prod }_{i , j} D ( {α}_{i} ) D ( {α}_{j} )$$

Where D is the Dirichlet distribution. Here the Dirichlet distribution is conjugate to the multinomial distribution, and hence a multinomial distribution can be fitted to consecutive data points in the buffer to update the counts of the α vector.

This method can be extended to other exponential family distributions explaining the state transition function in similar ways. Furthermore, the state transition can be compounded to be a mixture of multinomial distributions.

The method can also extend for nonexponential family distributions where either sampling methods can be used. Alternatively, a neural network function approximator can be used. In one embodiment, a forward pass from a state x(t) and control u(t) vector once concatenated passes through a sequence of neurons represented by affine transformations followed by non-linear activation functions, such as “relu”, “selu”, “tan h” etc., until a final fully connected layer where an output of x(t+d) exists. This is paired with a loss function, often a mean squatted error, although other functions such as Huber norm, L1 norm can be used for regression or softmax with cross entropy for categorical distributions as is the case for this embodiment.

By sampling a batch from the buffer and performing a forward pass, back propagation of the derivatives can use used to optimize the weights and biases of the affine transformation components in the neural network model. Once trained with sufficient data. The trained model can be used in the dynamic programming or optimization steps.

The buffer can be created from historical data or from simulated data. To validate the model, a sample of data where the resultant state transition x(t+d) in known is used to compare the predicted state transition x(t+d) from the real. This also serves to determine if the training is over fitting and under fitting and if regularization techniques need to be employed.

Preferably, a reward function is selected to maximize the similarity between a sensor measurement sequence γ_{w}(t₀:t₀+d)=(γ_{w}(t₀), γ_{w}(t₀+1), . . . , γ_{w}(t₀+d)) over a fixed length interval d∈N and a sequence generated by the model x_{rsd}(t+d)=x_{rsd}(t)+u_{dip}+η, γₜ(x_{rsd}(t₀:t₀+d))=(γₜ(x_{rsd}(t₀)), γₜ(x_{rsd}(t₀+1)), . . . , γₜ(x_{rsd}(t₀+d)))

r(x(t),x(t+1),u(t))=ƒ(γₜ(x_{rsd}(t:t+d)),γ_{w}(t:t+d))

Here ƒ can be defined to be the pointwise sum of squares error ƒ=Σᵢ₌ₜ^{i=t+d}(γₜ−γ_{w})² or a correlation function over the sequence such as the cosine similarity:

$$\frac{{{γ}_{t} ( {x}_{rsd} ( t \text{:} t + d ) )}^{T} {γ}_{w} ( t \text{:} t + d )}{‖ {γ}_{t} ( {x}_{rsd} ( t \text{:} t + d ) ‖ ‖ {γ}_{w} ( t \text{:} t + d ) ‖}$$

To test the performance of the algorithm, a time domain simulation of the drilling behavior is performed. Here a 2D drilling model based on the Pernedar Detournay (PD) model (L. Pernedar and E. Detournay, A Three-Dimensional Mathematical Model of Directional Drilling. PhD Thesis, 2013) is used to model the borehole propagation.

$${χΠΘ}_{i n c} ( t ) = - {M}_{b} [ {Θ}_{i n c} ( t ) - < {Θ}_{i n c} > ] + {F}_{b} [ {Θ}_{i n c} ( t ) - {Θ}_{i n c} ] + {\sum }_{i = 1}^{n - 1} [ \frac{{F}_{b} {M}_{i} - {F}_{i} {M}_{b} - {M}_{i} η Π}{η Π} ] ( < {Θ}_{inc , i} > - < {Θ}_{i n c} - \frac{χ}{η} {F}_{i} ( \frac{{Θ}_{inc , i - 1} - {Θ}_{inc , i}}{{x}_{i}} - \frac{{Θ}_{inc , i} - {Θ}_{inc , i + 1}}{{x}_{i + 1}} ) + \frac{{F}_{b} {M}_{w} - {F}_{w} {M}_{b} - {M}_{w} η Π}{η Π} Υ sin < {Θ}_{i} > - \frac{χ}{η} {F}_{w} Υ [ {Θ}_{i n c} ( t ) - < {Θ}_{i n c} > ] cos < {Θ}_{i} > \frac{{F}_{b} {M}_{r} - {F}_{r} {M}_{b} - {M}_{r} η Π}{η Π} ( {Γ}_{2} )$$

Here Mᵢ and Fᵢ are coefficients related to the forces and moments of the drilling assembly. The coefficients ξ and η are related to the geometric design of the bit. Θ_{inc,i} is the inclination angle of the i stabilizer. <Θ_{inc,i}> is the inclination angle between the i stabilizer and the (i+1) stabilizer. [symbol] is the weight-on-bit and Γ₂ is the control action applied. The position of the wellbore is obtained by integrating the inclination angle to give the x_{tvd} of the well.

x_{tvd}=∫ₜ_{₀}^{t=T} cos Θ_{inc}dt

The earth is modeled as a 2D unfaulted layer cake with parallel formation boundaries. The formation top is modeled as a gaussian process

x_{f}˜GP(m(x),k(x,x′))

with a mean function drawn from a random trajectory, and an appropriate choice of a kernel k. The relative stratigraphic distance x_{rsd}(t) is given by the difference of these two by

x_{rsd}(t)=x_{f}(t)−x_{tvd}

The petrophysical sensors with lower depth of investigation are given by a 1D table look up from a predetermined reference well γₜ(x_{rsd}).

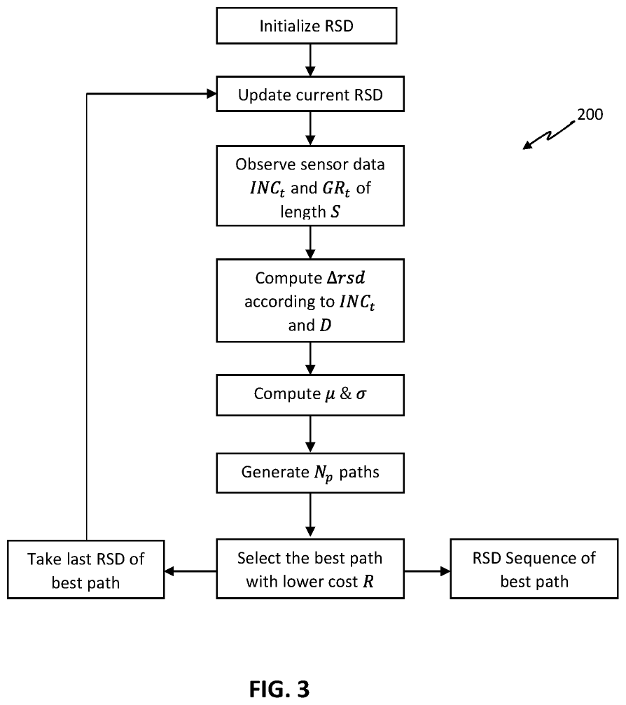

FIG. 3 illustrates another embodiment of a work flow of the present invention where the trained reinforcement learning agent is a trained MCTS reinforcement learning agent. The Monte Carlo Tree Search Algorithm as described in Rémi Coulom (2007). “Efficient Selectivity and Backup Operators in Monte-Carlo Tree Search”. Computers and Games, 5th International Conference, C G 2006, Turin, Italy, May 29-31, 2006. Revised Papers. H. Jaap van den Herik, Paolo Ciancarini, H. H. L. M. Donkers (eds.). is modified here to approximate a search over an enumerated set of all trajectories. These trajectories are captured by a tree data structure where the note represents stratigraphic position, and paths in the tree are feasible trajectories. The modified algorithm is illustrated in FIG. 3 as Monte Carlo Trajectory Sampling 200, where a distribution over trajectories is learned to guide the most probable trajectories for efficient searching.

For MCTS, inputs are:
a system model A and
a cost function that considers S steps of future cost,
interpolation I(typelog RSD, typelog GR),
initial formation dip D, and

start RSD rsd0.

Sensor data INCₜ, GRₜ of length S are observed. Changes in RSD Δrsd over an advancement in trajectory length of length S are determined according to inclination sensor data INCₜ and initial formation dip D. Based on the Δrsd, a Gaussian distribution N(μ, σ) is computed for actions. A simulation is performed using actions sampled out from N(μ, σ). Cost R of each trajectory sampled is computed according to GR (Gamma Ray) sensor data GRₜ and the type log. The trajectory with least cost R has the best RSD sequence. The number of trajectories sampled is high when Δrsd is high, or vice versa.

Output of the MCTS is an RSD sequence that minimizes the cost function. The algorithm is preferably:

Initialize the current RSD, curr_rsd = rsd0
Initialize centre, c = rsd0
for t = 0,1, ... do /* Iterate over stands of length S */

| | |
|---|---|
| \| | Observe INCₜ and GRₜ /* Sensor data of length S */ |
| \| | Compute change in RSD Δrsd according to INCₜ and initial formation dip D |
| \| | Update c according to Δrsd |
| \| | Compute mean μ = (c − curr_rsd)/S |
| \| | Compute sigma σ according to μ |
| \| | /* Search over Nₚ paths */ |
| \| | for p = 0,1, ... Nₚ do |

| | |
|---|---|
| \| \| | Set r̅s̅d̅₀̅ = curr_rsd /* each path starts with curr_rsd */ |
| \| \| | Set R(p) = 0 |
| \| \| | /* estimating over stand length S */ |
| \| \| | for k = 0,1, ... S do |

| | | |
|---|---|---|
| \| \| | \| | Sample action a from Gaussian distribution N(μ, σ) |
| \| \| | \| | Predict the next RSD, r̅s̅d̅ₖ̅₊̅₁̅ = A( r̅s̅d̅ₖ̅, a) |
| \| \| | \| | Compute the cost r according to GR(k), I(r̅s̅d̅ₖ̅₊̅₁̅) |
| \| \| | \| | Update R(p) = γ R (p) + r |

| | |
|---|---|
| \| \| | end |

| | |
|---|---|
| \| | end |
| \| | Select the best path with lower cost R |
| \| | Set curr_rsd to the last RSD in best path |
| | Take RSD sequence in best path |

end

Preferably, the reinforcement learning agent is trained using a simulation environment, more preferably using a simulation environment produced in accordance with the method described in “Method for Simulating a Coupled Geological and Drilling Environment” filed in the USPTO on the same day as the present application, as provisional application U.S. 62/712,490 filed 31 Jul. 2018, the entirety of which is incorporated by reference herein.

For example, the reinforcement learning agent may be trained by (a) providing a training earth model defining boundaries between formation layers and petrophysical properties of the formation layers in a subterranean formation comprising data selected from the group consisting of seismic data, data from an offset well and combinations thereof, and producing a set of model coefficients; (b) providing a toolface input corresponding to the set of model coefficients to a drilling attitude model for determining a drilling attitude state; (c) determining a drill bit position in the subterranean formation from the drilling attitude state; (d) feeding the drill bit position to the training earth model, and determining an updated set of model coefficients for a predetermined interval and a set of signals representing physical properties of the subterranean formation for the drill bit position; (e) inputting the set of signals to a sensor model for producing at least one sensor output and determining a sensor reward from the at least one sensor output; (f) correlating the toolface input and the corresponding drilling attitude state, drill bit position, set of model coefficients, and the at least one sensor output and sensor reward in the simulation environment; and (g) repeating steps b)-f) using the updated set of model coefficients from step d).

The drilling model for the simulation environment may be a kinematic model, a dynamical system model, a finite element model, and combinations thereof.

### Examples 1-4

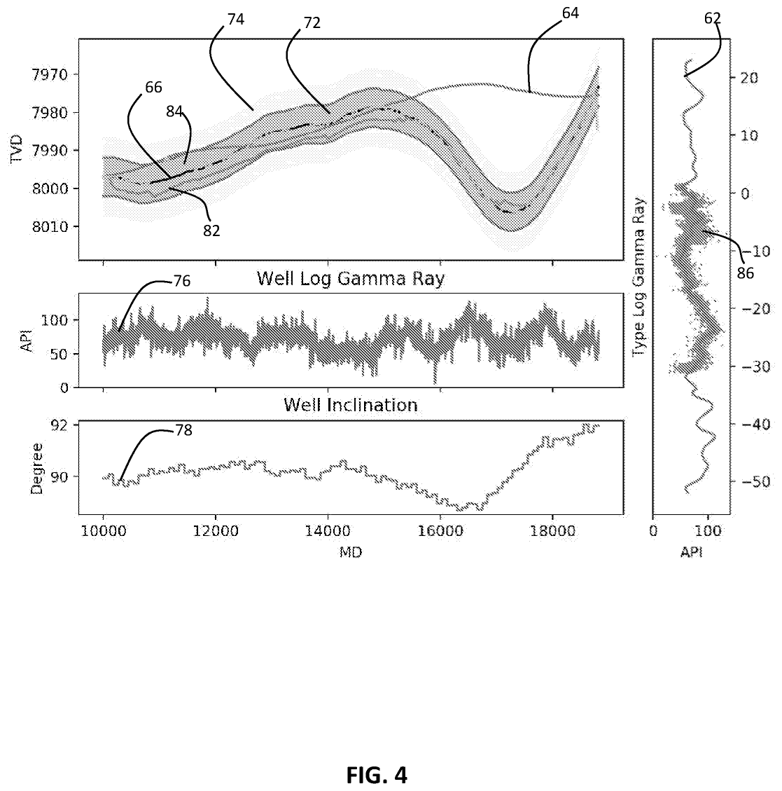

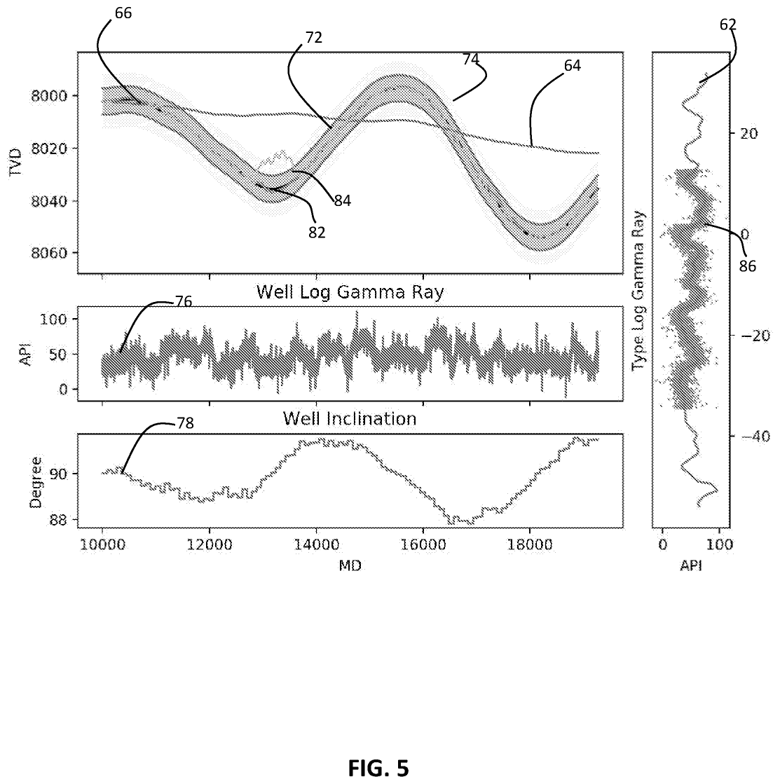

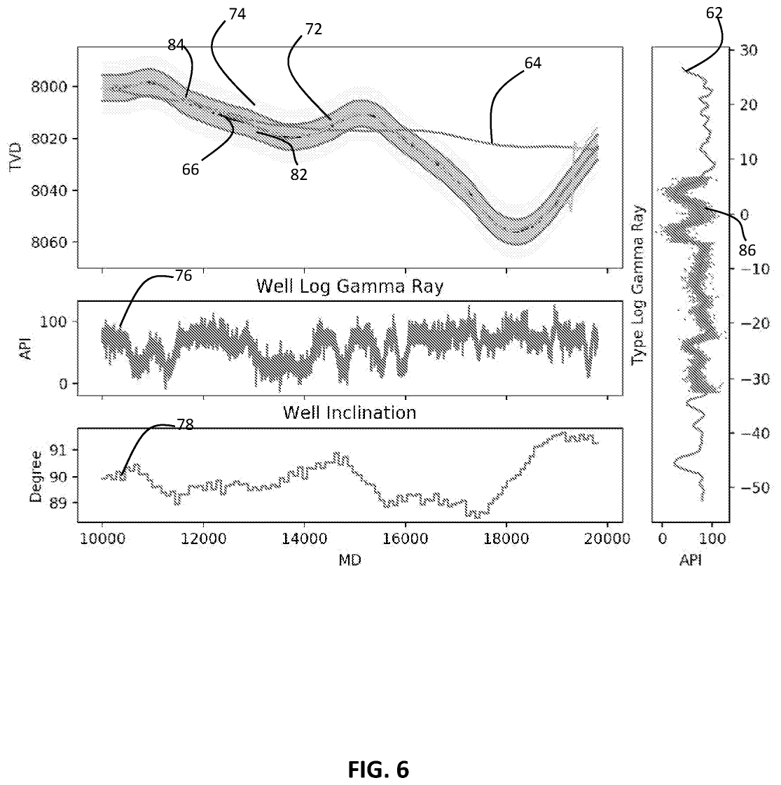

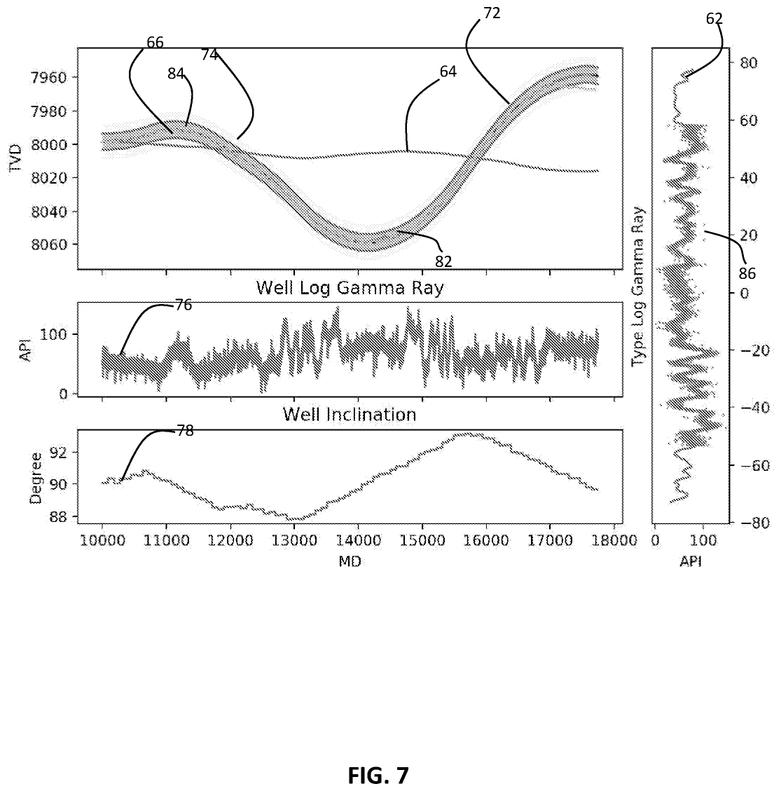

The method of the present invention was tested. Referring now to FIGS. 4-7, a synthetic well was generated based on an actual gamma ray log. The real data is identified by a type log gamma ray plot 62. Based on the type log gamma ray plot 62, a boundary 64 representing the top of a target formation was determined and a synthetic true well path 66 was generated. Region 72 represents a 1.5-m (5-foot) error about the true well path 66, while region 74 represents a 3-m (10-foot) error about the well path 66. The goal of the test was to match the true well path 66 as best as possible.

In each of Example 1-4, a Bayesian reinforcement learning agent was trained according to the method described in co-pending application entitled “Method for Simulating a Coupled Geological and Drilling Environment” filed in the USPTO on the same day as the present application.

Well log gamma ray data 76 was fed to the trained agent and a set of control inputs, in this case well inclination angle 78, was used to steer the well-boring along the true well path 66, according to the method described in co-pending application entitled “Process for Training a Deep Learning Process for Geological Steering Control” filed in the USPTO on the same day as the present application, as provisional application U.S. 62/712,506 filed 31 Jul. 2018, the entirety of which is incorporated by reference herein.

The well path 82 resulting from the Bayesian reinforcement learning agent and the well path 84 resulting from the trained agent with mean square error demonstrated good fit to the true well path 66. As shown in FIGS. 4-7, the fit of well paths 82 and 84 improved over time with a reward function described in the autonomous geosteering method.

While preferred embodiments of the present disclosure have been described, it should be understood that various changes, adaptations and modifications can be made therein without departing from the spirit of the invention(s) as claimed below.

1. A method of geosteering in a wellbore construction process, the method comprising the steps of:
providing an earth model defining boundaries between formation layers and petrophysical properties of the formation layers in a subterranean formation comprising data selected from the group consisting of seismic data, data from an offset well and combinations thereof;
comparing sensor measurements related to the wellbore construction process to the earth model;
obtaining an estimate from the earth model for a relative geometrical and geological placement of the well path with respect to a geological objective using a trained reinforcement learning agent; and
determining an output action based on the sensor measurement for influencing a future profile of the well path with respect to the estimate.

2. The method of claim 1, wherein the trained reinforcement learning agent is a trained Bayesian reinforcement learning agent.

3. The method of claim 1, wherein the trained reinforcement learning agent is a trained Monte Carlo Trajectory Sampling reinforcement learning agent.

4. The method of claim 1, wherein the output action is determined by maximizing the placement of the well path with respect to a geological datum.

5. The method of claim 4, wherein the geological datum is selected from the group consisting of a rock formation boundary, a geological feature, an offset well, an oil/water contact, an oil/gas contact, an oil/tar contact and combinations thereof.

6. The method of claim 4, wherein the estimate is determined by providing to the trained reinforcement learning agent:
a state space representation for a given depth for a position and a direction of the well path and the geological datum, having a discretized representation of the output action as a set of plausible geological datum changes;
a state transition function for determining a transition between the state space representation at depth t and depth t+1 conditional upon the output action;
an observational model for modeling the sensor measurements to the earth model;
a reward function;
a discount rate applied to the reward function for determining a discounted reward function; and
a value function representing a past sum of discounted rewards for the transition of depth running forward in time.

7. The method of claim 6, wherein an optimal output action for a most probable well path is solved with respect to the value function to minimize or maximize the expected sum of the reward function at a given depth.

8. The method of claim 6, wherein an optimum value function is determined by iterating on a maximum or minimum of the expected sum of the reward function at depth t with the value of the state space at depth t−1 with respect to state transition function, selecting the highest value state with respect to a constraint, and propagating forward in depth the output actions to determine an optimum formation interpretation.

9. The method of claim 6, wherein the state space is continuous.

10. The method of claim 6, the state transition function is pretrained on historical wells and or synthetic data, wherein the pretraining is selected from the group consisting of a neural network, a probabilistic graphical model, and combinations thereof.

11. The method of claim 6, wherein the discounted sum of rewards is based on discretized depth intervals in an arc length of the well path.

12. The method of claim 6, wherein the reward function is selected from the group consisting of a sequence similarity measure, a mean squared error reward function, a Huber loss reward function, a non-convex reward function and combination thereof.

13. The method of claim 6, wherein the observation model is a look-up from a type log or the earth model.

14. The method of claim 1, wherein the earth model is a static model.

15. The method of claim 1, wherein the earth model is a dynamic model that changes dynamically during the drilling process.

16. The method of claim 1, wherein the sensor measurements are provided as a streaming sequence.

17. The method of claim 1, wherein the sensor measurements are measurements obtained from sensors selected from the group consisting of gamma-ray detectors, neutron density sensors, porosity sensors, sonic compressional slowness sensors, resistivity sensors, nuclear magnetic resonance, mechanical properties, inclination, azimuth, roll angles, and combinations thereof.

18. The method of claim 1, wherein the reinforcement learning agent is trained in a simulation environment.

19. The method of claim 18, wherein the simulation environment is produced by a training method comprising the steps of:
a) providing a training earth model defining boundaries between formation layers and petrophysical properties of the formation layers in a subterranean formation comprising data selected from the group consisting of seismic data, data from an offset well and combinations thereof, and producing a set of model coefficients;
b) providing a toolface input corresponding to the set of model coefficients to a drilling attitude model for determining a drilling attitude state;
c) determining a drill bit position in the subterranean formation from the drilling attitude state;
d) feeding the drill bit position to the training earth model, and determining an updated set of model coefficients for a predetermined interval and a set of signals representing physical properties of the subterranean formation for the drill bit position;
e) inputting the set of signals to a sensor model for producing at least one sensor output and determining a sensor reward from the at least one sensor output;
f) correlating the toolface input and the corresponding drilling attitude state, drill bit position, set of model coefficients, and the at least one sensor output and sensor reward in the simulation environment; and
g) repeating steps b)-f) using the updated set of model coefficients from step d).

20. The method of claim 19, wherein the drilling attitude model is selected from the group consisting of a kinematic model, a dynamical system model, a finite element model, and combinations thereof.

21. The method of claim 1, wherein the output action is selected from the group consisting of curvature, roll angle, set points for inclination, set points for azimuth, Euler angle, rotation matrix quaternions, angle axis, position vector, position Cartesian, polar, and combinations thereof.
